(19) United States
(12) Patent Application Publication
(10) Pub. No.: US 2009/0230509 A1
(43) Pub. Date: Sep. 17, 2009

(54) FINGER CAPACITOR STRUCTURES

(75) Inventors: Malcolm MacIntosh, Escondido, CA (US); Arya Reza Behzad, Poway, CA (US)

Correspondence Address: GARLICK HARRISON & MARKISON, P.O. BOX 160727, AUSTIN, TX, 78716-0727, US

(73) Assignee: Broadcom Corporation, Irvine, CA (US)

(21) Appl. No.: 12/275,074

(22) Filed: Nov. 20, 2008

Related U.S. Application Data
(60) Provisional application No. 61/035,980, filed on Mar. 12, 2008.

(51) Int. Cl. H01L 29/92

(52) U.S. Cl. 257/532; 257/E29.343

(57) ABSTRACT

A capacitive structure formed in an Integrated Circuit (IC) includes a plurality of capacitor node conductor pairs, each including a first node conductor having a base portion and a plurality of finger portions and a second node conductor having a base portion and a plurality of finger portions that are inter digitized with the plurality of finger portions of the first node conductor. Dielectric is horizontally disposed between the first node conductor and the second node conductor. At least one dielectric layer vertically separates adjacent metal layers, each dielectric layer including dielectric disposed between the adjacent metal layers, a plurality of first node vias vertically connecting finger portions of first node conductors of the adjacent metal layers, and a plurality of second node vias vertically connecting finger portions of the second node conductors of the adjacent metal layers. The plurality of first node vias and plurality of second node vias have staggered spacing to preclude laterally adjacent first node vias and second node vias.

### CROSS REFERENCES TO PRIORITY APPLICATIONS

This application claims priority under 35 U.S.C. 119(e) to U.S. Provisional Application Ser. No. 61/035,980, filed Mar. 12, 2008, and having a common title with the present application, which is incorporated herein by reference in its entirety for all purposes.

### BACKGROUND

1. Technical Field

This invention relates generally to integrated circuits; and more particularly to capacitors formed in the integrated circuits.

2. Related Art

Communication systems are known to support wireless and wire lined communications between wireless and/or wire lined communication devices. Such communication systems range from national and/or international cellular telephone systems to the Internet to point-to-point in-home wireless networks. Communication systems typically operate in accordance with one or more communication standards. For instance, wired communication systems may operate according to one or more versions of the Ethernet standard, the System Packet Interface (SPI) standard, or various other standards. Wireless communication systems may operate in accordance with one or more standards including, but not limited to, IEEE 802.11x, WiMAX, Bluetooth, advanced mobile phone services (AMPS), digital AMPS, global system for mobile communications (GSM), code division multiple access (CDMA), local multi-point distribution systems (LMDS), multi-channel-multi-point distribution systems (MMDS), and/or variations thereof.

Depending on the type of wireless communication system, a wireless communication device, such as a cellular telephone, two-way radio, personal digital assistant (PDA), personal computer (PC), laptop computer, home entertainment equipment, et cetera communicates directly or indirectly with other wireless communication devices. For direct communications (also known as point-to-point communications), the participating wireless communication devices tune their receivers and transmitters to the same channel or channels (e.g., one of the plurality of radio frequency (RF) carriers of the wireless communication system) and communicate over that channel(s). For indirect wireless communications, each wireless communication device communicates directly with an associated base station (e.g., for cellular services) and/or an associated access point (e.g., for an in-home or in-building wireless network) via an assigned channel. To complete a communication connection between the wireless communication devices, the associated base stations and/or associated access points communicate with each other directly, via a system controller, via the public switch telephone network, via the Internet, and/or via some other wide area network.

For each wireless communication device to participate in wireless communications, it includes a built-in radio transceiver (i.e., receiver and transmitter) or is coupled to an associated radio transceiver (e.g., a station for in-home and/or in-building wireless communication networks, RF modem, etc.). Typically, the transceiver includes a data modulation stage and an RF stage. The data modulation stage converts between data and baseband signals in accordance with the particular wireless communication standard. The RF stage converts between baseband signals and RF signals. The RF stage may be a direct conversion transceiver that converts directly between baseband and RF or may include one or more intermediate frequency stages.

The RF stage includes a plurality of components that will be described further herein with respect to embodiments of the present invention. RF stage components often include analog circuitry, including capacitors. Because the RF stage components are constructed within one or more Integrated Circuits (ICs), the RF stage components of the ICs often include capacitors that are formed within the IC itself. One type of capacitor formed within the IC itself is referred to as a “finger capacitor.” Finger capacitors include conductive and dielectric elements, typically formed within multiple metal layers. The dimensions and spacing of the conductive and dielectric elements of the finger capacitors determine the amount of capacitance provided by the finger capacitors. With the dimensions of ICs decreasing with time, the capacitance provided by the finger capacitors also decreases. Thus, a need exists for improved finger capacitor structures that may be used with available IC manufacturing processes.

### BRIEF SUMMARY OF THE INVENTION

The present invention is directed to apparatus and methods of operation that are further described in the following Brief Description of the Drawings, the Detailed Description of the Drawings, and the claims. Other features and advantages of the present invention will become apparent from the following detailed description of the invention made with reference to the accompanying drawings.

### BRIEF DESCRIPTION OF THE DRAWINGS

FIG. 1 is a schematic block diagram illustrating a wireless communication system in accordance with the present invention;

FIG. 2 is a schematic block diagram illustrating a wireless communication device in accordance with the present invention;

FIG. 3 is a diagrammatic sectional side view of a capacitive structure formed in an Integrated Circuit (IC) according to one or more embodiments of the present invention;

FIG. 4 is a diagrammatic sectional top view of a metal layer of a capacitive structure formed in an IC according to one or more embodiments of the present invention;

FIG. 5 is a partial diagrammatic sectional side view of a capacitive structure formed in an IC according to one or more embodiments of the present invention taken along a different section than FIG. 3;

FIG. 6 is a diagrammatic sectional side view of another capacitive structure formed in an IC according to one or more embodiments of the present invention;

FIG. 7 is a diagrammatic top view of a conductor pair of a finger capacitor structure constructed according to an embodiment of the present invention;

FIG. 8 is a diagrammatic sectional side view of a portion of a finger capacitor structure constructed according to an embodiment of the present invention as viewed along section A;

FIGS. 9 and 10 are diagrammatic sectional side views of a portion of the finger capacitor structure of FIG. 7 taken along sections B and C, respectively according to a first particular embodiment; and

FIGS. 11 and 12 are diagrammatic sectional side views of a portion of the finger capacitor structure of FIG. 7 taken along sections B and C, respectively according to a second particular embodiment.

### DETAILED DESCRIPTION OF THE DRAWINGS

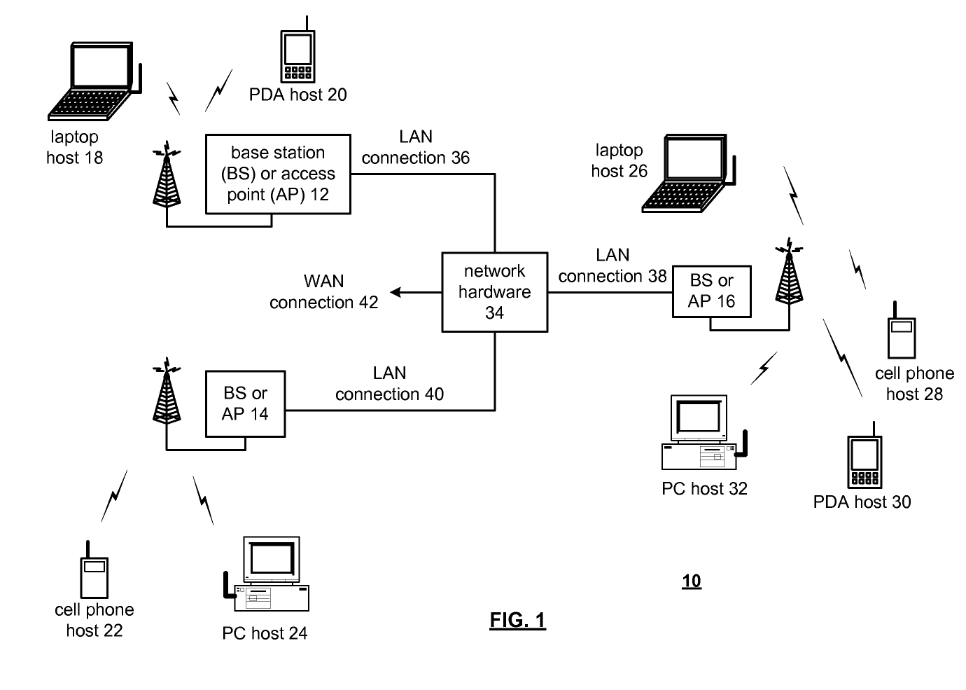

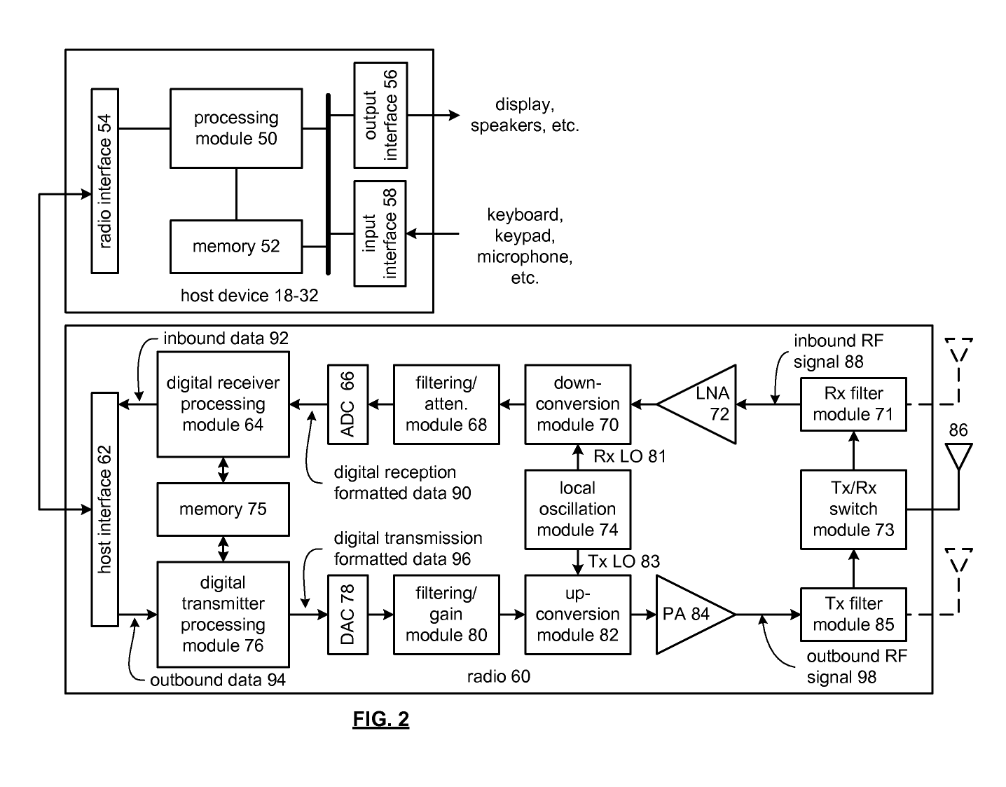

FIG. 1 is a schematic block diagram illustrating a communication system 10 that includes a plurality of base stations and/or access points 12-16, a plurality of wireless communication devices 18-32 and a network hardware component 34. The wireless communication devices 18-32 may be laptop host computers 18 and 26, personal digital assistant hosts 20 and 30, personal computer hosts 24 and 32, cellular telephone hosts 22 and 28, and/or any other type of device that supports wireless communications. The details of the wireless communication devices will be described with reference to FIG. 2.

The base stations or access points 12-16 are operably coupled to the network hardware 34 via local area network connections 36, 38 and 40. The network hardware 34, which may be a router, switch, bridge, modem, system controller, et cetera provides a wide area network connection 42 for the communication system 10. Each of the base stations or access points 12-16 has an associated antenna or antenna array to communicate with the wireless communication devices in its area. Typically, the wireless communication devices register with a particular base station or access point 12-14 to receive services from the communication system 10. For direct connections (i.e., point-to-point communications), wireless communication devices communicate directly via an allocated channel.

Typically, base stations are used for cellular telephone systems and like-type systems, while access points are used for in-home or in-building wireless networks. Regardless of the particular type of communication system, each wireless communication device includes a built-in radio and/or is coupled to a radio. The radio includes a highly linear amplifiers and/or programmable multi-stage amplifiers as disclosed herein to enhance performance, reduce costs, reduce size, and/or enhance broadband applications.

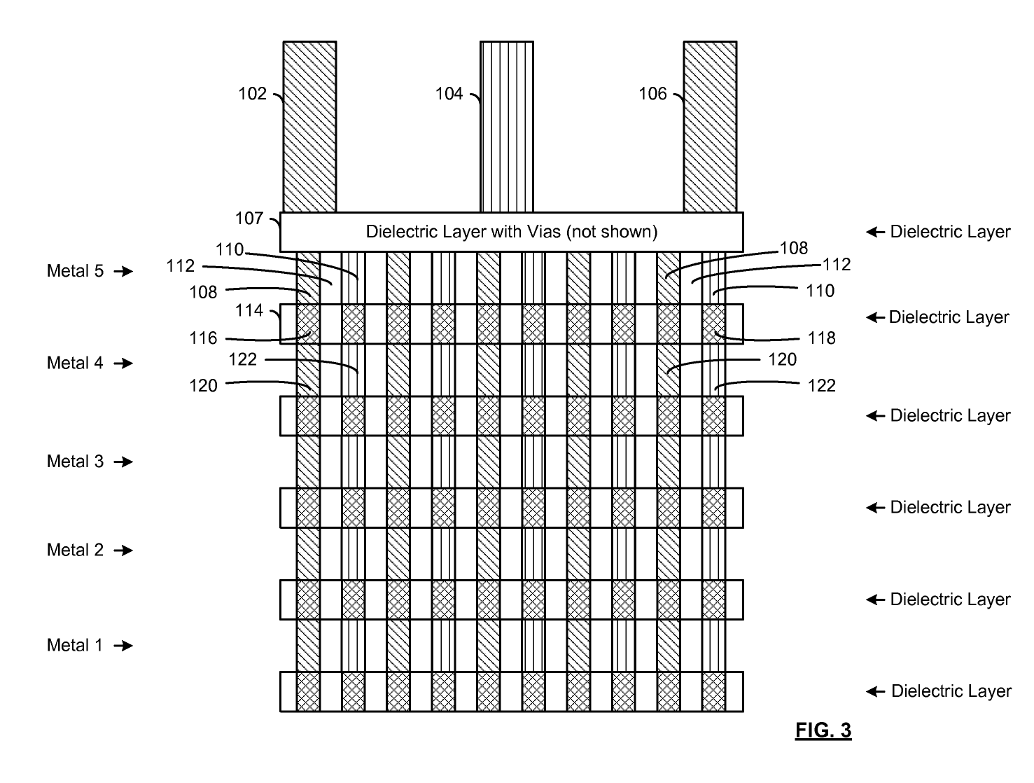

Some or all of these communication devices 18-32 are constructed to include Integrated Circuits (ICs) that support Radio Frequency (RF) communications. Of those communication devices 18-32 that include such ICs that support RF communications, some or all of these communication devices include ICs having finger capacitors constructed according to embodiments of the present invention. These embodiments of finger capacitors constructed according to the present invention will be described further with reference to FIGS. 3-12. The finger capacitor constructs of the embodiments of the present invention may be used with other ICs as well.

FIG. 2 is a schematic block diagram illustrating a wireless communication device that includes the host device 18-32 and an associated radio 60. For cellular telephone hosts, the radio 60 is a built-in component. For personal digital assistants hosts, laptop hosts, and/or personal computer hosts, the radio 60 may be built-in or may be an externally coupled component that couples to the host device 18-32 via a communication link, e.g., PCI interface, PCMCIA interface, USB interface, or another type of interface.

As illustrated, the host device 18-32 includes a processing module 50, memory 52, radio interface 54, input interface 58, and output interface 56. The processing module 50 and memory 52 execute the corresponding instructions that are typically done by the host device. For example, for a cellular telephone host device, the processing module 50 performs the corresponding communication functions in accordance with a particular cellular telephone standard.

The radio interface 54 allows data to be received from and sent to the radio 60. For data received from the radio 60 (e.g., inbound data), the radio interface 54 provides the data to the processing module 50 for further processing and/or routing to the output interface 56. The output interface 56 provides connectivity to an output display device such as a display, monitor, speakers, et cetera, such that the received data may be displayed. The radio interface 54 also provides data from the processing module 50 to the radio 60. The processing module 50 may receive the outbound data from an input device such as a keyboard, keypad, microphone, et cetera via the input interface 58 or generate the data itself. For data received via the input interface 58, the processing module 50 may perform a corresponding host function on the data and/or route it to the radio 60 via the radio interface 54.

Radio 60 includes a host interface 62, digital receiver processing module 64, an analog-to-digital converter 66, a filtering/gain/attenuation module 68, an IF mixing down conversion stage 70, a receiver filter 71, a low noise amplifier 72, a transmitter/receiver switch 73, a local oscillation module 74, memory 75, a digital transmitter processing module 76, a digital-to-analog converter 78, a filtering/gain/attenuation module 80, an IF mixing up conversion stage 82, a power amplifier 84, a transmitter filter module 85, and an antenna 86. The antenna 86 may be a single antenna that is shared by the transmit and receive paths as regulated by the Tx/Rx switch 77, or may include separate antennas for the transmit path and receive path. The antenna implementation will depend on the particular standard to which the wireless communication device is compliant.

The digital receiver processing module 64 and the digital transmitter processing module 76, in combination with operational instructions stored in memory 75, execute digital receiver functions and digital transmitter functions, respectively. The digital receiver functions include, but are not limited to, digital intermediate frequency to baseband conversion, demodulation, constellation demapping, decoding, and/or descrambling. The digital transmitter functions include, but are not limited to, scrambling, encoding, constellation mapping, modulation, and/or digital baseband to IF conversion. The digital receiver and transmitter processing modules 64 and 76 may be implemented using a shared processing device, individual processing devices, or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on operational instructions. The memory 75 may be a single memory device or a plurality of memory devices. Such a memory device may be a read-only memory, random access memory, volatile memory, non-volatile memory, static memory, dynamic memory, flash memory, and/or any device that stores digital information. Note that when the processing module 64 and/or 76 implements one or more of its functions via a state machine, analog circuitry, digital circuitry, and/or logic circuitry, the memory storing the corresponding operational instructions is embedded with the circuitry comprising the state machine, analog circuitry, digital circuitry, and/or logic circuitry. The memory 75 stores, and the processing module 64 and/or 76 executes, operational instructions that facilitate functionality of the device. In some embodiments, the combination of the digital receiver processing module, the digital transmitter processing module, and the memory 75 may be referred to together as a “baseband processor.”

In operation, the radio 60 receives outbound data 94 from the host device via the host interface 62. The host interface 62 routes the outbound data 94 to the digital transmitter processing module 76, which processes the outbound data 94 in accordance with a particular wireless communication standard (e.g., IEEE802.11a, IEEE802.11b, IEEE802.11g, IEEE802.11n, Bluetooth, WiMAX, et cetera) to produce digital transmission formatted data 96. The digital transmission formatted data 96 will be a digital base-band signal or a digital low IF signal, where the low IF typically will be in the frequency range of one hundred kilohertz to a few megahertz.

The digital-to-analog converter 78 converts the digital transmission formatted data 96 from the digital domain to the analog domain. The filtering/gain/attenuation module 80 filters and/or adjusts the gain of the analog signal prior to providing it to the IF mixing stage 82. The IF mixing stage 82 directly converts the analog baseband or low IF signal into an RF signal based on a transmitter local oscillation 83 provided by local oscillation module 74. The power amplifier 84 amplifies the RF signal to produce outbound RF signal 98, which is filtered by the transmitter filter module 85. The antenna 86 transmits the outbound RF signal 98 to a targeted device such as a base station, an access point and/or another wireless communication device.

The radio 60 also receives an inbound RF signal 88 via the antenna 86, which was transmitted by a base station, an access point, or another wireless communication device. The antenna 86 provides the inbound RF signal 88 to the receiver filter module 71 via the Tx/Rx switch 77, where the Rx filter 71 bandpass filters the inbound RF signal 88. The Rx filter 71 provides the filtered RF signal to low noise amplifier 72, which amplifies the signal 88 to produce an amplified inbound RF signal. The low noise amplifier 72 provides the amplified inbound RF signal to the IF mixing module 70, which directly converts the amplified inbound RF signal into an inbound low IF signal or baseband signal based on a receiver local oscillation 81 provided by local oscillation module 74. The down conversion module 70 provides the inbound low IF signal or baseband signal to the filtering/gain/attenuation module 68. The filtering/gain/attenuation module 68 may be implemented in accordance with the teachings of the present invention to filter and/or attenuate the inbound low IF signal or the inbound baseband signal to produce a filtered inbound signal.

The analog-to-digital converter 66 converts the filtered inbound signal from the analog domain to the digital domain to produce digital reception formatted data 90. The digital receiver processing module 64 decodes, descrambles, demaps, and/or demodulates the digital reception formatted data 90 to recapture inbound data 92 in accordance with the particular wireless communication standard being implemented by radio 60. The host interface 62 provides the recaptured inbound data 92 to the host device 18-32 via the radio interface 54.

As one of average skill in the art will appreciate, the wireless communication device of FIG. 2 may be implemented using one or more integrated circuits. For example, the host device may be implemented on one integrated circuit, the digital receiver processing module 64, the digital transmitter processing module 76 and memory 75 may be implemented on a second integrated circuit, and the remaining components of the radio 60, less the antenna 86, may be implemented on a third integrated circuit. As an alternate example, the radio 60 may be implemented on a single integrated circuit. As yet another example, the processing module 50 of the host device and the digital receiver and transmitter processing modules 64 and 76 may be a common processing device implemented on a single integrated circuit. Further, the memory 52 and memory 75 may be implemented on a single integrated circuit and/or on the same integrated circuit as the common processing modules of processing module 50 and the digital receiver and transmitter processing module 64 and 76.

Some of the components of the radio 50 may include finger capacitors constructed according to embodiments of the present invention. In particular, the RF components of the radio 50, including PA 84, Tx filter module 85, Tx/Rx switch module 73, Rx filter module 71, and/or LNA 72 (among other of the components of the radio 50) may include finger capacitors 50 constructed according to embodiments of the present invention. Such finger capacitor structures will be described further with reference to FIGS. 3-12, herein.

FIG. 3 is a diagrammatic sectional side view of a capacitive structure formed in an IC according to one or more embodiments of the present invention. Generally, the capacitive structure is formed in an IC and includes a plurality of metal layers and a plurality of dielectric layers. Referred to in FIG. 3 are metal layers 1 through 5 and dielectric layers residing between the metal layers and/or adjacent the metal layers.

Each of a plurality of metal layers of the IC includes a plurality of conductors disposed at least partially in parallel with one another and dielectric material disposed between the plurality of conductors. For example metal layer 5, includes a plurality of conductors, some of which are referred to as conductors 108 and 110. The remainder of the conductors is not referred to specifically by reference number. The dielectric material disposed between these conductors 108 and 110 is referred to as dielectric 112. Each of the conductors of the dielectric layer corresponds to one of a first node and a second node. The first node corresponds to structures 102 and 106 above dielectric layer 107. Of the metal 5 layer, conductors 108 and those other conductors having consistent pattern in FIG. 3 correspond to the first node while conductors 110 and those other conductors having a consistent pattern correspond to the second node. Thus, conductors 108 corresponding to the first node electrically couple to each other and electrically couple to structures 102 and 106 by way of vias of dielectric layer 107. Likewise, conductors 110 corresponding to the second node electrically couple to each other and to structure 104 by way of vias of dielectric layer 107.

Each other of the metal layers 1-4 also includes a plurality of conductors. Those conductors of metal layers 1-4 having a pattern consistent with the pattern of conductors 108 also correspond to the first node and electrically couple to each other and electrically couple to structures 102 and 106 by way of vias of dielectric layer 107 and by way of other vias. Likewise, those conductors of metal layers 1-4 having a pattern consistent with the pattern of conductors 110 also correspond to the second node and electrically couple to each other conductor of the second node, including structure 104 by way of vias of dielectric layer 107 and by way of other vias. For example, conductors 120 of metal layer 4 correspond to the first node and electrically couple to other conductors (of the same and differing metal layers) of the first node. Likewise, conductors 122 of metal layer 4 correspond to the second node and electrically couple to other conductors (of the same and differing metal layers) of the second node. This structure and organization follows in each other of the metal layers.

Each dielectric layer of the plurality of dielectric layers separates adjacent metal layers of the IC and includes insulating portions and vias. For example, a dielectric layer disposed between metal layer 4 and metal layer 5 includes an insulating portion 114 and vias 116 and 118. Each of the vias is disposed to couple conductors of adjacent metal layers. For example, via 116 couples conductor 108 of metal layer 5 to conductor 120 of metal layer 4. Likewise, via 118 couples conductor 110 of metal layer 5 to conductor 122 of metal layer 4.

With respect to the structure of FIG. 3, conductors of the first node of a first metal layer resides spatially above and in parallel with conductors of the first node of a second metal layer, the first metal layer and second metal layer separated by a dielectric layer of the plurality of dielectric layers. Further, conductors of the second node of the first metal layer residing spatially above and in parallel with conductors of the second node of the second metal layer. With particular reference to metal layers 4 and 5, conductor 108 of the first node of metal layer 5 resides spatially above and in parallel with conductor 120 of the first node of metal layer 4, with metal layers 108 and 120 separated by a dielectric layer of the plurality of dielectric layers. Further, still with particular reference to metal layers 4 and 5, conductor 110 of the second node of metal layer 5 resides spatially above and in parallel with conductor 122 of the second node of metal layer 4. This structure is substantially consistent with the other metal layers of FIG. 3.

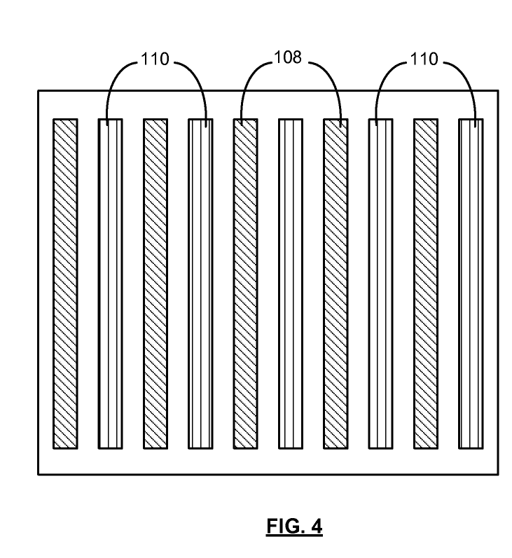

FIG. 4 is a diagrammatic sectional top view of a metal layer of a capacitive structure formed in an IC according to one or more embodiments of the present invention. Referring particularly to the structure of FIG. 4, with dimensions exaggerated for clarity, the plurality of conductors are disposed in parallel with one another and each of the plurality of metal layers has conductive plates having a height, a thickness, and a length. As shown in FIG. 4, the conductors of the first node 108 and the conductors of the second node 110 each has a conductive plate shape, with the conductors being separated by dielectric. With the structure of FIG. 3, the separation of the conductors and their thickness may violate minimum processing rule dimensions. For example, in a 0.13 um process, the metal width may be decreased to 0.1 um while retaining a separation between conductors of 0.13 um. With the structure of FIG. 4, at least some of the plurality of conductors have a substantially cuboid shape. Alternate embodiments of the finger capacitors of the present invention may include differing numbers of conductors that are oriented in differing manners without departing from the present invention.

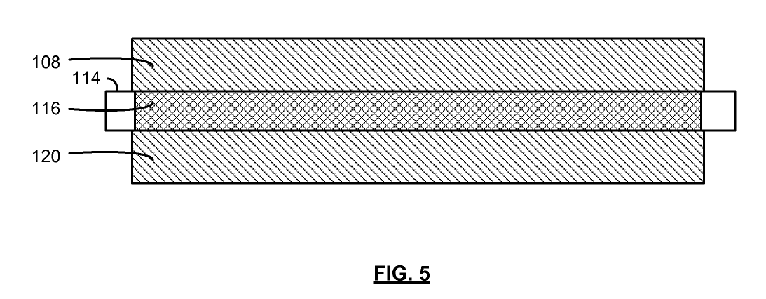

FIG. 5 is a partial diagrammatic sectional side view of a capacitive structure formed in an IC according to one or more embodiments of the present invention taken along a different section than FIG. 3. With the structure of FIG. 5, the vias 116 disposed within the dielectric layer are elongated, correspond to the conductors 108 and 120 of adjacent metal layers and couple to the conductors of the adjacent metal layer. The structure of the vias of FIG. 5 may be referred to as having “via walls.” With the structure of FIG. 5, the total area and mass of the conductors of the first node and second node are greater, increasing the capacitance of the structure.

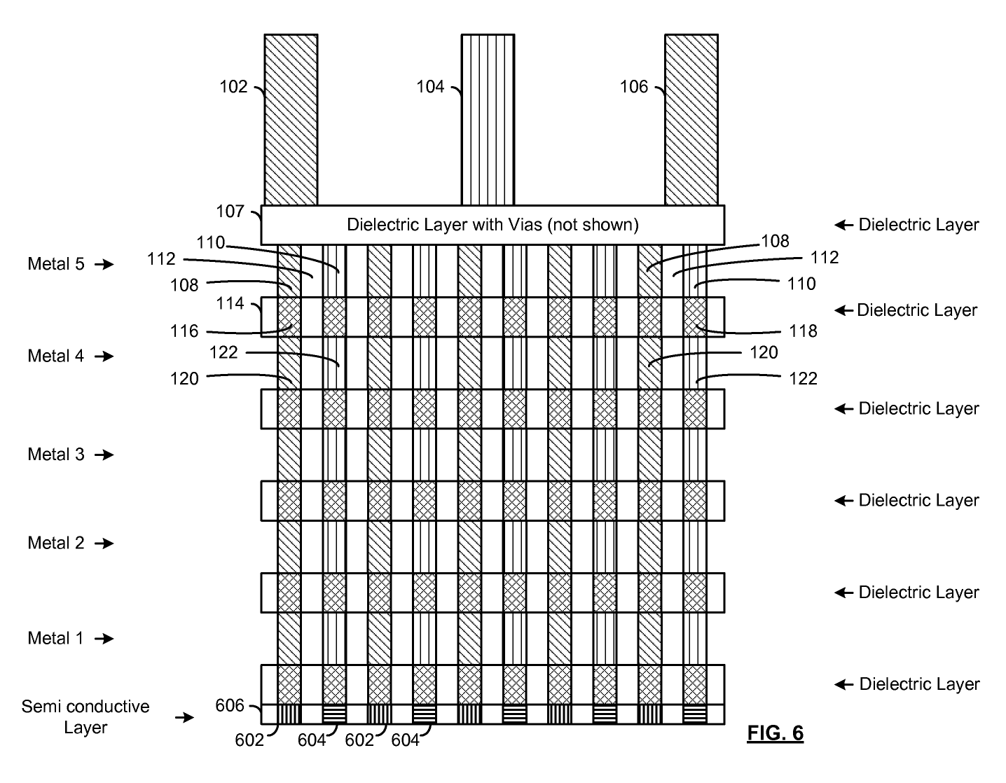

FIG. 6 is a diagrammatic sectional side view of another capacitive structure formed in an IC according to one or more embodiments of the present invention. As compared to the structure of FIG. 3, the capacitive structure of FIG. 6 further includes a semi conductive layer disposed adjacent to a dielectric layer of the IC and includes conductive portions 602 and 604 disposed within the semi conductive layer that correspond to vias of the adjacent dielectric layer and couple to the vias of the adjacent dielectric layer. The insulating portions 606 are disposed between the conducting portions 602 and 604. Conducting portions 602 correspond to the first node and electrically couple to other components of the first node. Conducting portions 604 correspond to the second node and electrically couple to other components of the second node. With the embodiment of FIG. 6, conductive portions may be poly silicon. The conductors of FIG. 6 as well as FIGS. 3-5 may be copper, aluminum, or another conductive metal/substance used as a conductor with in an IC. Usage of the poly silicon layer to increase capacitance of the capacitive structure may be had with other capacitive structures as well without departing from the teachings of the present invention.

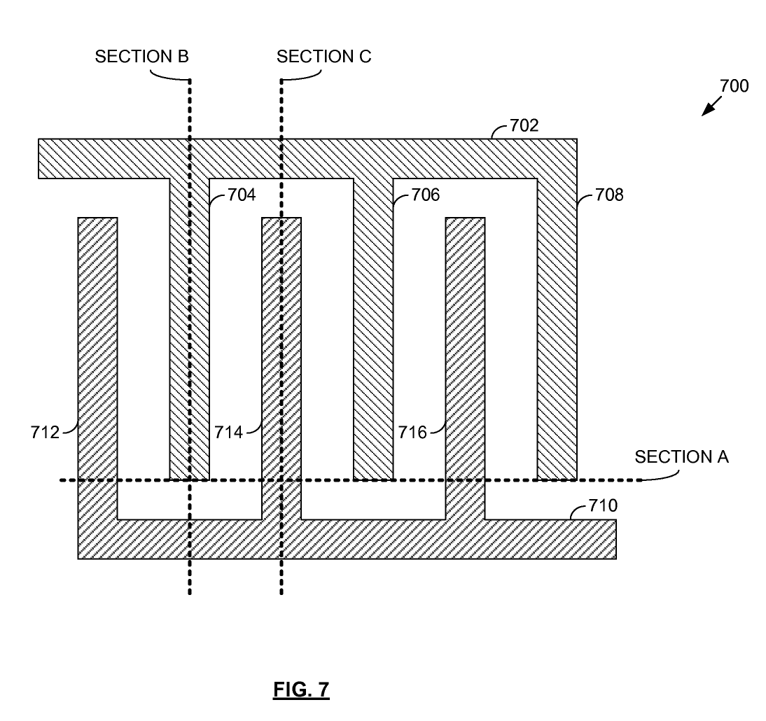

FIG. 7 is a diagrammatic top view of a conductor pair of a finger capacitor structure constructed according to an embodiment of the present invention. An IC finger capacitor structure of the present invention includes a plurality of capacitor node conductor pairs. Each capacitor node conductor pair 700 is respective to a metal layer, e.g., formed in a respective metal layer. Each capacitor node conductor pair 700 includes a first node conductor and a second node conductor. The first node conductor has a base portion 702 and a plurality of finger portions 704, 706, and 708. The second node conductor has a base portion 710 and a plurality of finger portions 712, 714, and 716 that are inter digitized with the plurality of finger portions of the first node conductor. Also formed in the metal layer with the capacitor node conductor pair 700 is dielectric horizontally disposed between the first node conductor and the second node conductor to insulate the conductors from one another.

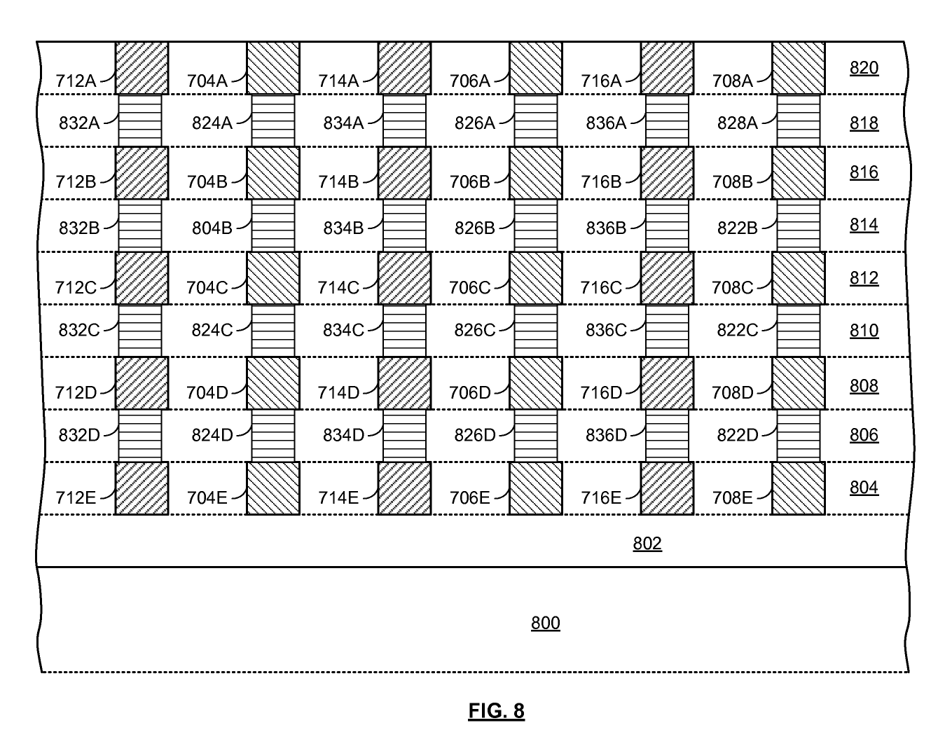

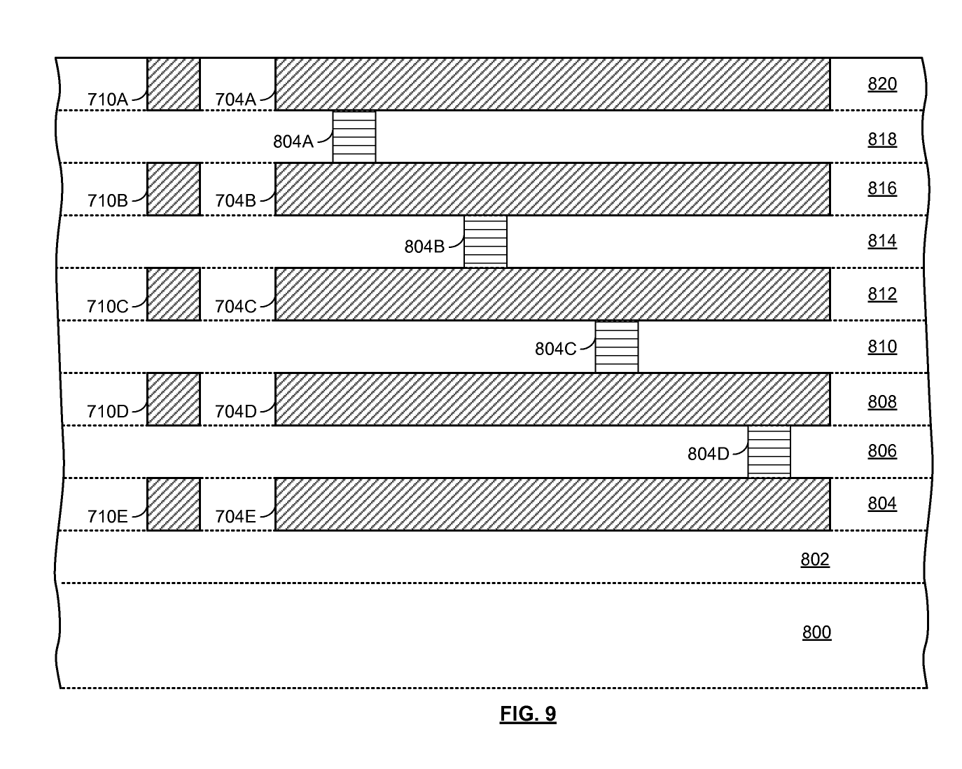

The IC finger capacitor structure also includes at least one dielectric layer vertically separating adjacent metal layers. These dielectric layers have been previously described and will be described further with reference to FIGS. 8-12. Generally, each dielectric layer includes dielectric disposed between the adjacent metal layers, a plurality of first node vias, and a plurality of second node vias. The plurality of first node vias vertically connects finger portions of first node conductors of the adjacent metal layers. Further, the plurality of second node vias vertically connects finger portions of the second node conductors of the adjacent metal layers. As will be described further herein with reference to FIGS. 9-12 the plurality of first node vias and the plurality of second node vias having staggered spacing to preclude laterally adjacent first node vias and second node vias. With this staggered spacing the risk of dielectric breakdown between first node vias and second node vias is reduced to ensure proper operation of the IC over a longer lifetime.

FIG. 8 is a diagrammatic sectional side view of a portion of a finger capacitor structure constructed according to an embodiment of the present invention as viewed along section A. Generally, FIG. 8 shows a side cutaway of an IC but with transparency detail that extends along the IC from the viewpoint of section A to show multiple vias of each node. Metal layer 820 includes first node conductor finger portions 704A, 706A, and 708A as well as second node conductor finger portions 712A, 714A, and 716A. Metal layer 816 includes first node conductor finger portions 704B, 706B, and 708B as well as second node conductor finger portions 712B, 714B, and 716B. Metal layer 812 includes first node conductor finger portions 704C, 706C, and 708C as well as second node conductor finger portions 712C, 714C, and 716C. Metal layer 808 includes first node conductor finger portions 704D, 706D, and 708D as well as second node conductor finger portions 712D, 714D, and 716D. Metal layer 804 includes first node conductor finger portions 704E, 706E, and 708E as well as second node conductor finger portions 712E, 714E, and 716E.

Also shown in FIG. 8 are a plurality of dielectric layers, each having at least one first node via and at least one second node via. Particularly, dielectric layer 818 includes first node vias 824A, 826A, and 822A and second node vias 832A, 834A, and 836A. Dielectric layer 814 includes first node vias 824B, 826B, and 822B and second node vias 832B, 834B, and 836B. Dielectric layer 810 includes first node vias 824C, 826C, and 822C and second node vias 832C, 834C, and 836C. Dielectric layer 806 includes first node vias 824C, 826C, and 822C and second node vias 832C, 834C, and 836C. Also shown in FIG. 8 are poly silicon layer 802 and semiconductor layer 800. Semi-conductive components of a communication circuit are formed in semi conductive layer 800 that include transistors, resistors, and other circuit components. poly silicon layer 802 may also include active circuit components and/or optional capacitor elements constructed according to embodiments of the present invention.

The view of FIG. 8 does not show the staggered spacing of the vias of the finger capacitor structure. Such staggered spacing will be further illustrated in FIGS. 9-11. However, that being said the staggered spacing of the vias precludes their laterally adjacent location. For example, referring to first node via 824A and second node vias 832A and 834A, the IC is constructed so that the first node vide 824A is not laterally adjacent to either second node via 832A or 834A. Thus, as a result of this lateral separated the second node vias 832A and 834A will be laterally separated by dielectric that fully extends between the vias 832A and 834A. This staggered lateral spacing, as contrasted to adjacent lateral location, provides additional dielectric isolation between all first node vias and second node vias, making the finger capacitor structure less prone to failure due to dielectric breakdown than prior finger capacitor structures.

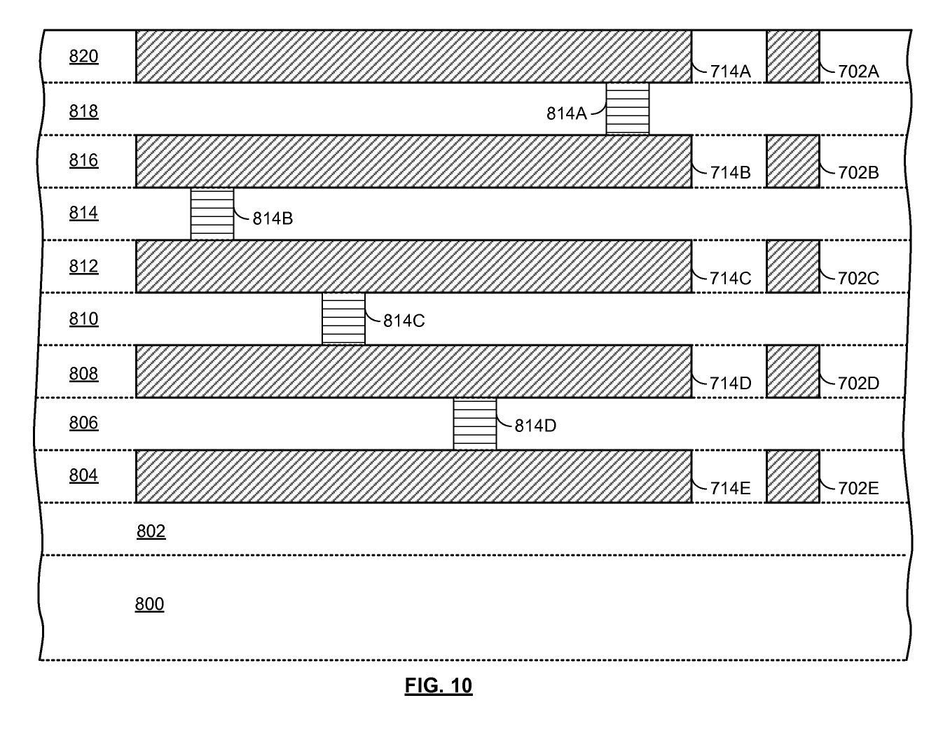

FIGS. 9 and 10 are diagrammatic sectional side views of a portion of the finger capacitor structure of FIG. 7 taken along sections B and C, respectively according to a first particular embodiment. Referring particularly to FIG. 9, first node vias 804A, 804B, 804C, and 804D are shown to reside in respective dielectric layers 818, 814, 810, and 806. These first node vias 804A, 804B, 804C, and 804D have staggered spacing with regard to one another according to one particular construct. Referring particularly to FIG. 10, second node vias 814A, 814B, 814C, and 814D are shown to reside in respective dielectric layers 818, 814, 810, and 806. These second node vias have staggered spacing with respect to one another according to the particular construct. Note, however, viewing both FIGS. 9 and 10 that the first node vias and second node vias of common dielectric layers have staggered spacing with regard to one another so that first and second node vias of common dielectric layers do not reside adjacent one another. Particularly, first node via 804A and second node via 814A of dielectric layer 818 have lateral spacing so that they do not reside adjacent one another. Further, first node via 804B and second node via 814B of dielectric layer 814 do not reside adjacent one another. Moreover, first node via 804C and second node via 814C of dielectric layer 810 do not reside adjacent one another. Finally, first node via 804D and second node via 814D of dielectric layer 806 do not reside adjacent one another. With this structure, all first node vias are robustly electrically isolated from all second node vias to prevent dielectric breakdown there between within common dielectric layers.

The structure of FIGS. 8-10 (and that of FIGS. 8 and 11-12) may be applied with regard to node conductors formed in a poly silicon layer as well. With this construct, the finger capacitor structure further includes a semi conductive layer having a first node conductor, a second node conductor, and dielectric horizontally disposed between the first node conductor and the second node conductor. Moreover, the finger capacitor structure includes a dielectric layer vertically separating the semi conductive layer and an adjacent metal layer. The dielectric layer includes dielectric disposed between the semi conductive layer and the adjacent metal layer, a plurality of first node vias vertically connecting the first node conductor of the semi conductive layer to a first node conductor of the adjacent metal layer, and a plurality of second node vias vertically connecting the second node conductor of the semi conductive layer to a second node conductor of the adjacent metal layer.

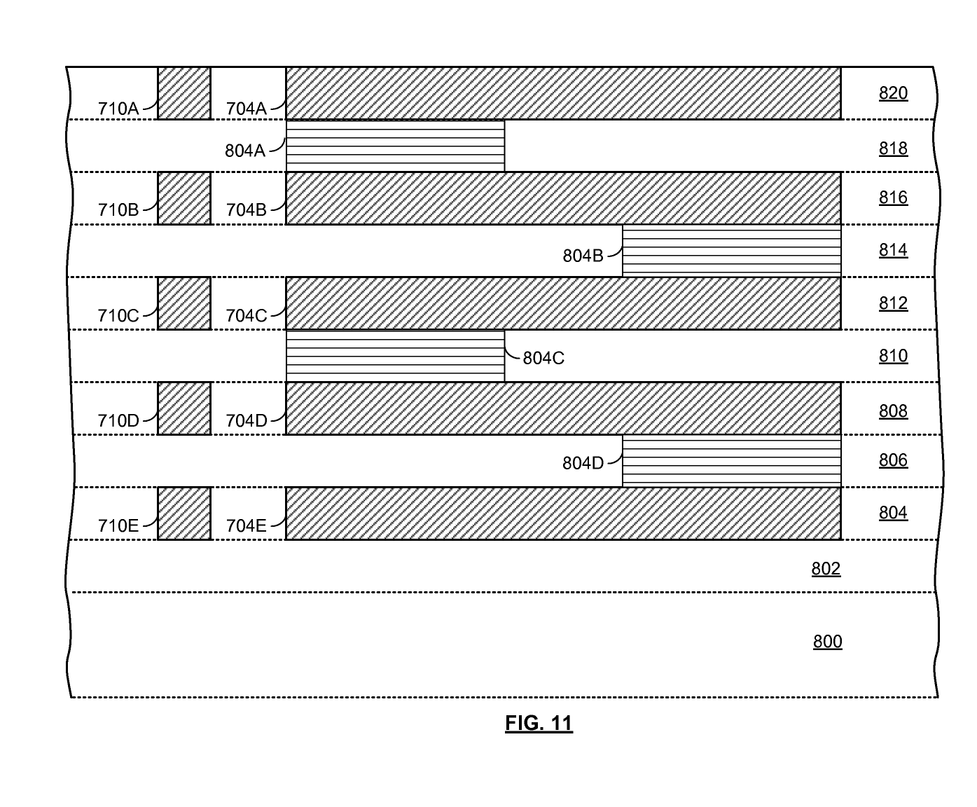

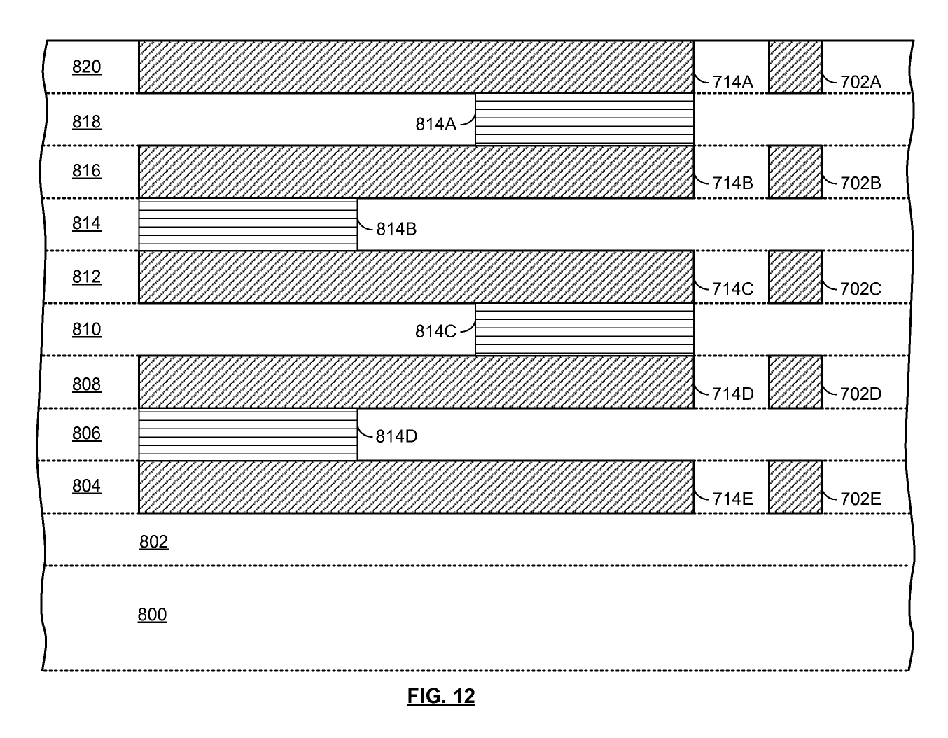

FIGS. 11 and 12 are diagrammatic sectional side views of a portion of the finger capacitor structure of FIG. 7 taken along sections B and C, respectively according to a second particular embodiment. Referring particularly to FIG. 11, first node vias 804A, 804B, 804C, and 804D are shown to reside in respective dielectric layers 818, 814, 810, and 806. These first node vias 804A, 804B, 804C, and 804D have staggered spacing with regard to one another according to one particular construct. Referring particularly to FIG. 12, second node vias 814A, 814B, 814C, and 814D are shown to reside in respective dielectric layers 818, 814, 810, and 806. These second node vias have staggered spacing with respect to one another according to the particular construct. Note, however, viewing both FIGS. 11 and 12 that the first node vias and second node vias of common dielectric layers have staggered spacing with regard to one another so that first and second node vias of common dielectric layers do not reside adjacent one another. Particularly, first node via 804A and second node via 814A of dielectric layer 818 have lateral spacing so that they do not reside adjacent one another. Further, first node via 804B and second node via 814B of dielectric layer 814 do not reside adjacent one another. Moreover, first node via 804C and second node via 814C of dielectric layer 810 do not reside adjacent one another. Finally, first node via 804D and second node via 814D of dielectric layer 806 do not reside adjacent one another. With this structure, all first node vias are robustly electrically isolated from all second node vias to prevent dielectric breakdown there between within common dielectric layers.

As is shown in FIGS. 8-12, the vias may take differing lengths (and have differing dimensions) in differing embodiments. For example, in some constructs, the plurality of finger portions of the first node conductor each have a finger thickness, a finger width, and a finger length. Further, the plurality of first node vias each have a via thickness, a via width, and a via length. In some embodiments, for at least some first node vias, the via length greater than the finger width. In other embodiments, for at least some first node vias, the via length is greater substantially equal to the finger width. In some particular constructs of the finger capacitor structure the plurality of metal layers include two metal layers and the at least one dielectric layer comprises a single dielectric layer. In other embodiments, the plurality of metal layers comprise at least three metal layers and the at least one dielectric layer comprises at least two dielectric layers.

The terms “circuit” and “circuitry” as used herein may refer to an independent circuit or to a portion of a multifunctional circuit that performs multiple underlying functions. For example, depending on the embodiment, processing circuitry may be implemented as a single chip processor or as a plurality of processing chips. Likewise, a first circuit and a second circuit may be combined in one embodiment into a single circuit or, in another embodiment, operate independently perhaps in separate chips. The term “chip”, as used herein, refers to an integrated circuit. Circuits and circuitry may comprise general or specific purpose hardware, or may comprise such hardware and associated software such as firmware or object code.

The present invention has also been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claimed invention.

The present invention has been described above with the aid of functional building blocks illustrating the performance of certain significant functions. The boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality. To the extent used, the flow diagram block boundaries and sequence could have been defined otherwise and still perform the certain significant functionality. Such alternate definitions of both functional building blocks and flow diagram blocks and sequences are thus within the scope and spirit of the claimed invention. One of average skill in the art will also recognize that the functional building blocks, and other illustrative blocks, modules and components herein, can be implemented as illustrated or by discrete components, application specific integrated circuits, processors executing appropriate software and the like or any combination thereof.

As may be used herein, the terms “substantially” and “approximately” provides an industry-accepted tolerance for its corresponding term and/or relativity between items. Such an industry-accepted tolerance ranges from less than one percent to fifty percent and corresponds to, but is not limited to, component values, integrated circuit process variations, temperature variations, rise and fall times, and/or thermal noise. Such relativity between items ranges from a difference of a few percent to magnitude differences. As may also be used herein, the term(s) “coupled to” and/or “coupling” and/or includes direct coupling between items and/or indirect coupling between items via an intervening item (e.g., an item includes, but is not limited to, a component, an element, a circuit, and/or a module) where, for indirect coupling, the intervening item does not modify the information of a signal but may adjust its current level, voltage level, and/or power level. As may further be used herein, inferred coupling (i.e., where one element is coupled to another element by inference) includes direct and indirect coupling between two items in the same manner as “coupled to”. As may even further be used herein, the term “operable to” indicates that an item includes one or more of power connections, input(s), output(s), etc., to perform one or more its corresponding functions and may further include inferred coupling to one or more other items. As may still further be used herein, the term “associated with”, includes direct and/or indirect coupling of separate items and/or one item being embedded within another item. As may be used herein, the term “compares favorably”, indicates that a comparison between two or more items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1.

The present invention has also been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claimed invention.

Moreover, although described in detail for purposes of clarity and understanding by way of the aforementioned embodiments, the present invention is not limited to such embodiments. It will be obvious to one of average skill in the art that various changes and modifications may be practiced within the spirit and scope of the invention, as limited only by the scope of the appended claims.

1. An Integrated Circuit (IC) finger capacitor structure comprising:
a plurality of capacitor node conductor pairs, each of a respective metal layer and each comprising:
a first node conductor having a base portion and a plurality of finger portions;
a second node conductor having a base portion and a plurality of finger portions that are inter digitized with the plurality of finger portions of the first node conductor; and
dielectric horizontally disposed between the first node conductor and the second node conductor;
at least one dielectric layer vertically separating adjacent metal layers, each dielectric layer comprising
dielectric disposed between the adjacent metal layers; and
a plurality of first node vias vertically connecting finger portions of first node conductors of the adjacent metal layers; and
a plurality of second node vias vertically connecting finger portions of the second node conductors of the adjacent metal layers, the plurality of first node vias and plurality of second node vias having staggered spacing to preclude laterally adjacent first node vias and second node vias.

2. The finger capacitor structure of claim 1, wherein:
the plurality of finger portions of the first node conductor each have a finger thickness, a finger width, and a finger length;
the plurality of first node vias each have a via thickness, a via width, and a via length; and
for at least some first node vias, the via length greater than the finger width.

3. The finger capacitor structure of claim 1, wherein:
the plurality of finger portions of the first node conductor each have a finger thickness, a finger width, and a finger length;
the plurality of first node vias each have a via thickness, a via width, and a via length; and
for at least some first node vias, the via length greater substantially equal to the finger width.

4. The finger capacitor structure of claim 1, wherein:
the plurality of metal layers comprise two metal layers; and
the at least one dielectric layer comprises a single dielectric layer.

5. The finger capacitor structure of claim 1, wherein:
the plurality of metal layers comprise at least three metal layers; and
the at least one dielectric layer comprises at least two dielectric layers.

6. The finger capacitor structure of claim 1, further comprising:
a semi conductive layer including:
a first node conductor;
a second node conductor; and
dielectric horizontally disposed between the first node conductor and the second node conductor; and
a dielectric layer vertically separating the semi conductive layer and an adjacent metal layer, the dielectric layer including:
dielectric disposed between the semi conductive layer and the adjacent metal layer; and
a plurality of first node vias vertically connecting the first node conductor of the semi conductive layer to a first node conductor of the adjacent metal layer; and
a plurality of second node vias vertically connecting the second node conductor of the semi conductive layer to a second node conductor of the adjacent metal layer.

7. An Integrated Circuit (IC) comprising:
communication circuitry; and
a capacitor coupled to the communication circuitry and including:
a plurality of capacitor node conductor pairs, each of a respective metal layer and each comprising:
a first node conductor having a base portion and a plurality of finger portions;
a second node conductor having a base portion and a plurality of finger portions that are inter digitized with the plurality of finger portions of the first node conductor; and
dielectric horizontally disposed between the first node conductor and the second node conductor;
at least one dielectric layer vertically separating adjacent metal layers, each dielectric layer comprising
dielectric disposed between the adjacent metal layers; and
a plurality of first node vias vertically connecting finger portions of first node conductors of the adjacent metal layers; and
a plurality of second node vias vertically connecting finger portions of the second node conductors of the adjacent metal layers, the plurality of first node vias and plurality of second node vias having staggered spacing to preclude laterally adjacent first node vias and second node vias.

8. The integrated circuit of claim 7, wherein:
the plurality of finger portions of the first node conductor each have a finger thickness, a finger width, and a finger length;
the plurality of first node vias each have a via thickness, a via width, and a via length; and
for at least some first node vias, the via length greater than the finger width.

9. The integrated circuit of claim 7, wherein:
the plurality of finger portions of the first node conductor each have a finger thickness, a finger width, and a finger length;
the plurality of first node vias each have a via thickness, a via width, and a via length; and
for at least some first node vias, the via length greater substantially equal to the finger width.

10. The integrated circuit of claim 7, wherein:
the plurality of metal layers comprise two metal layers; and
the at least one dielectric layer comprises a single dielectric layer.

11. The integrated circuit of claim 7, wherein:
the plurality of metal layers comprise at least three metal layers; and
the at least one dielectric layer comprises at least two dielectric layers.

12. The integrated circuit of claim 7, further comprising:
a semi conductive layer disposed adjacent to a dielectric layer of the integrated circuit and including:
a first node conductor;
a second node conductor; and
dielectric horizontally disposed between the first node conductor and the second node conductor; and
a dielectric layer vertically separating the semi conductive layer and an adjacent metal layer, the dielectric layer including:
dielectric disposed between the semi conductive layer and the adjacent metal layer; and
a plurality of first node vias vertically connecting the first node conductor of the semi conductive layer to a first node conductor of the adjacent metal layer; and
a plurality of second node vias vertically connecting the second node conductor of the semi conductive layer to a second node conductor of the adjacent metal layer.
